(19) United States
(12) Patent Application Publication
(10) Pub. No.: US 2026/0071992 A1
(43) Pub. Date: Mar. 12, 2026

(54) THRESHOLD VOLTAGE ADJUSTABLE FIELD EFFECT TRANSISTOR BIOSENSOR USING TRI-LAYER ELECTRODES

(71) Applicant: INTERNATIONAL BUSINESS MACHINES CORPORATION, ARMONK, NY (US)

(72) Inventors: Takashi Ando, Eastchester, NY (US); Sufi Zafar, Briarcliff Manor, NY (US)

(21) Appl. No.: 18/829,129

(22) Filed: Sep. 9, 2024

(51) Int. Cl. G01N 27/414; B81B 7/02; B81C 1/00; G01N 27/333

(52) U.S. Cl. CPC G01N 27/4145; B81B 7/02; B81C 1/00166; G01N 27/333; B81B 2201/0214

(57) ABSTRACT

A microelectronic structure for bio-sensing includes a field-effect-transistor having a channel layer. A first layer of SiO₂ is arranged on the channel layer, and a second layer of HfO₂ is arranged on top of the first layer. A tri-layer metal electrode is arranged on the top of the second layer, the tri-layer metal electrode includes a bottom layer, an alloy layer on top of the bottom layer, and a top layer. A third layer constructed of an oxide material is arranged on top of the tri-layer metal electrode. A thickness of the bottom layer or the alloy layer of the tri-layer metal electrode is based on a pH of a test solution.

### BACKGROUND

### Technical Field

The present disclosure generally relates to devices used for analyte detection, and more specifically, to a Field Effect Transistor (FET) biosensor.

### Description of the Related Art

In recent years, an FET sensor has been functionalized after fabrication by attaching a biolayer to a sensing surface to bind to target analytes.

### SUMMARY

A microelectronic structure for bio-sensing includes a field-effect transistor having a channel layer. A first layer of SiO₂ is arranged on the channel layer, and a second layer of HfO₂ is arranged on top of the first layer. A tri-layer metal electrode is arranged on top of the second layer, the tri-layer metal electrode includes a bottom layer, an alloy layer on top of the bottom layer, and a top layer. A third layer constructed of an oxide material is on top of the tri-layer metal electrode. A thickness of the bottom layer or the alloy layer of the tri-layer metal electrode is based on a pH of a test solution.

In an embodiment, a microelectronic structure includes a field-effect-transistor (FET) having a channel layer. A first layer constructed of SiO2 is on the channel layer. A second layer constructed of HfO₂ is on top of the first layer. A tri-layer metal electrode is on top of the second layer, the tri-layer metal electrode includes a bottom layer, an alloy layer on top of the bottom layer, and a top layer. A third layer constructed of an oxide material is on top of the tri-layer metal electrode. A thickness of the bottom layer of the tri-layer metal electrode is based on a pH of a test solution.

In an embodiment, which may be combined with the preceding embodiment, a threshold voltage (Vt) of the FET is set based on the thickness of the bottom layer of the tri-layer metal electrode.

In an embodiment, which may be combined with one or more of the preceding embodiments, the thickness of the bottom layer is configured to increase based on an increase in the pH of the test solution.

In an embodiment, which may be combined with one or more of the preceding embodiments, the thickness of the bottom layer of the tri-layer metal electrode is between 5 to 100 Angstroms.

In an embodiment, which may be combined with one or more of the preceding embodiments, the alloy layer of the tri-layer metal electrode is an Al alloy selected from the group consisting of TiAl, TiAlC, TaAl, TaAlc, AiC, or Al.

In an embodiment, which may be combined with one or more of the preceding embodiments, the bottom layer of the tri-layer metal electrode is constructed of TiN, the alloy layer of the tri-layer metal electrode is an Al alloy, and the bottom layer of the tri-layer metal electrode is constructed of TiN.

In an embodiment, which may be combined with one or more of the preceding embodiments, the oxide material of the third layer is selected from the group consisting of HfO₂, SiO₂, or Al₂O₃.

In an embodiment, which may be combined with one or more of the preceding embodiments, the oxide material of the third layer includes a sensing surface exposed for contact with the test solution.

In an embodiment, which may be combined with one or more of the preceding embodiments, a reference electrode is arranged to charge the test solution in contact with the sensing surface of the oxide material of the third layer.

In an embodiment, a microelectronic structure includes a field-effect transistor (FET) having a channel layer. A first layer constructed of SiO2 is on the channel layer. A second layer constructed of HfO₂ is on top of the first layer. A tri-layer metal electrode is on top of the second layer, the tri-layer metal electrode includes a bottom layer, an alloy layer on top of the bottom layer, and a top layer. A third layer constructed of an oxide material is on top of the tri-layer metal electrode. A thickness of the alloy layer of the tri-layer metal electrode is based on a pH of a test solution.

In an embodiment, which may be combined with the preceding embodiment, a threshold voltage (Vt) of the FET is set based on the thickness of the alloy layer of the tri-layer metal electrode.

In an embodiment, which may be combined with one or more of the preceding embodiments, the thickness of the alloy layer is configured to decrease based on an increase in the pH of the test solution.

In an embodiment, which may be combined with one or more of the preceding embodiments, the thickness of the alloy layer of the tri-layer metal electrode is between 5 to 100 Angstroms.

In an embodiment, which may be combined with one or more of the preceding embodiments, the alloy layer of the tri-layer metal electrode is an Al alloy selected from the group consisting of TiAl, TiAlC, TaAl, TaAlc, AiC, or Al.

In an embodiment, which may be combined with one or more of the preceding embodiments, the bottom layer of the tri-layer metal electrode comprises TiN, the alloy layer of the tri-layer metal electrode comprises an Al alloy, and the bottom layer of the tri-layer metal electrode comprises TiN.

In an embodiment, which may be combined with one or more of the preceding embodiments, the oxide material of the third layer is selected from the group consisting of HfO₂, SiO₂, or Al₂O₃.

In an embodiment, which may be combined with one or more of the preceding embodiments, the oxide material of the third layer includes a sensing surface exposed for contact with the test solution.

In an embodiment, which may be combined with one or more of the preceding embodiments, a reference electrode is arranged to charge the test solution in contact with the sensing surface of the oxide material of the third layer.

In an embodiment, a method of manufacturing a microelectronic structure for bio-sensing includes providing a field-effect-transistor (FET) including a channel layer. A first layer constructed of SiO2 is arranged on the channel layer. A second layer constructed of HfO₂ is arranged on top of the first layer. A tri-layer metal is arranged electrode on the top of the second layer, the tri-layer metal electrode includes a bottom layer, an alloy layer on top of the bottom layer, and a top layer. A third layer constructed of an oxide material is arranged on top of the tri-layer metal electrode. A thickness of the alloy layer or the bottom layer of the tri-layer metal electrode is based on a pH of a test solution.

In an embodiment that may be combined with the preceding embodiment, the threshold voltage (Vt) of the FET is set based on the thickness of the bottom layer or the alloy layer of the tri-layer metal electrode.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates an FET sensor.

FIG. 1B is a graph showing a sensing signal vs a gate voltage for an FET sensor such as shown in FIG. 1A.

FIG. 1C illustrates a Vₜ shift of an FET sensor based on the pH of different test solutions.

FIG. 1D illustrates a Vₜ dependence of an FET sensor based on a negatively charged biolayer.

FIG. 1E illustrates a Vₜ dependence of an FET sensor based on a positively charged biolayer.

FIG. 2 illustrates an FET sensor having a first bottom TiN thickness for a relatively low pH solution, consistent with an illustrative embodiment.

FIG. 3 illustrates an FET sensor having a second bottom TiN thickness for a relatively high pH solution, consistent with an illustrative embodiment.

FIG. 4 illustrates an FET sensor with a first Al alloy thickness for a relatively low pH solution, consistent with an illustrative embodiment.

FIG. 5 illustrates an FET sensor with a second Al thickness for a relatively high pH solution, consistent with an illustrative embodiment.

FIG. 6 is a flowchart illustrating the operations to construct an FET sensor consistent with an illustrative embodiment.

### DETAILED DESCRIPTION

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings.

As used herein, a “relatively low pH” and a “relatively high pH” are relative to a neutral pH of 7. For example, a solution with a relatively low pH has a pH of about 6, and another solution with a relatively high pH has a pH of about 8. However, it is also to be understood that the microstructure of the present disclosure may be constructed for operation with a test solution at a pH of 0 to 14.

As used herein, the thickness of the bottom layer of the tri-layer metal electrode is typically a practical range of about 5 to 50 Angstroms.

### Overview

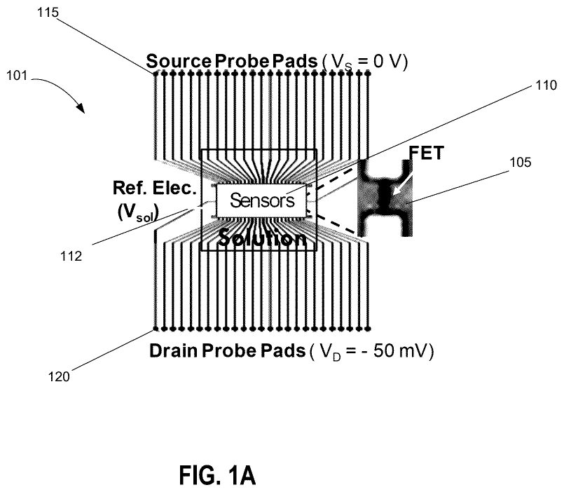

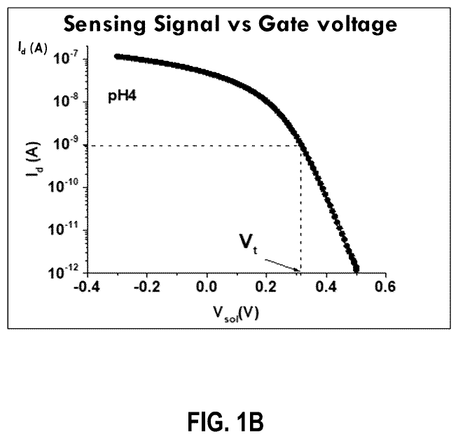

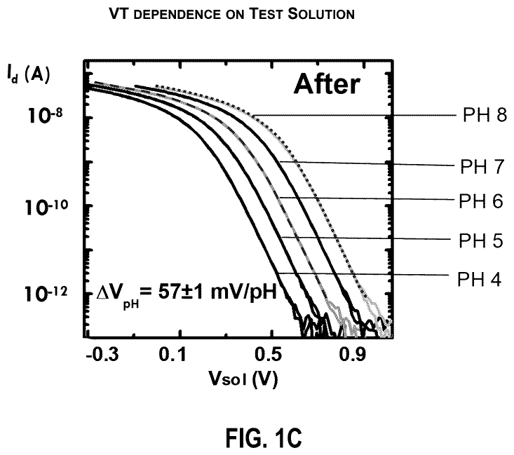

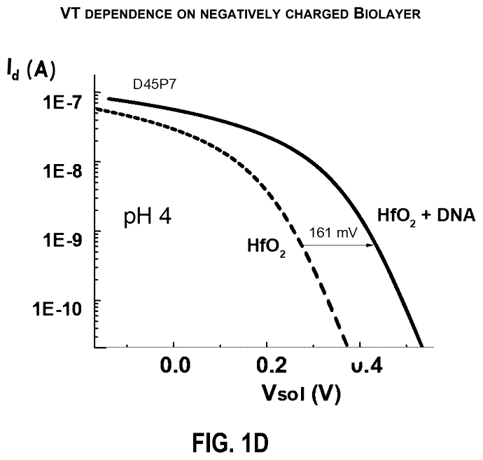

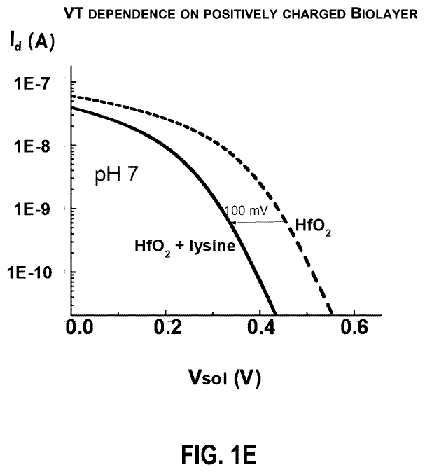

FIG. 1A shows a conventional FET sensor 101 and FIG. 1B is a graph showing a sensing signal vs a gate voltage. In a partially enlarged view shown in FIG. 1A, the FET 105 and sensor 110 are shown. The FET sensor 110 may be constructed of a plurality of biofilm sensors that sense a solution. A reference electrode 112 is a gate voltage applied to the solution Vsol arranged on the sensor. Source probe pads 115 and drain probe pads 120 are connected to the sensor 110. Referring to FIG. 1B, a drain current I_{d} is a function of the gate voltage applied to the solution. The FET threshold Vₜ, which is the threshold at which the FET turns on, is sensitive to the pH of the solution being tested. As shown in the graph, when testing for an analyte in a solution with a pH of 4, the threshold voltage Vₜ is about 0.3 volts with an I_{d} of 10⁻⁹. Thus, the threshold voltage of the conventional FET sensor depends on the analyte to be detected and the pH of the solution. Accordingly, Vₜ is not fixed by the fabrication process but depends on the diagnostic application.

Post fabrication, the FET sensor is functionalized by attaching a biolayer to its sensing surface that preferentially binds target analytes. Different biolayers are attached for detecting different analytes. The different biolayers are charged and modify the Vₜ. The net charge on a biolayer depends on its composition. In addition, Vₜ is impacted by the pH of the test solution in contact with the sensing surface of the FET.

FIG. 1C illustrates a Vₜ shift of an FET sensor based on the pH of different test solutions. There are shown pH solutions ranging from a pH of 4 to a pH of 8. The Vₜ is shown to increase with an increase in pH for an HfO₂ FET sensor.

FIG. 1D illustrates a Vₜ dependence of an FET sensor based on a negatively charged biolayer. The Vₜ is shown to increase when the Hafnium dioxide (HfO₂) is coated with a biolayer made of negatively charged 25 nucleotide long DNA strands.

FIG. 1E illustrates a Vₜ dependence of an FET sensor based on a positively charged biolayer. The Vₜ is shown to decrease when the sensing surface is coated with a biolayer made of positively charged lysine.

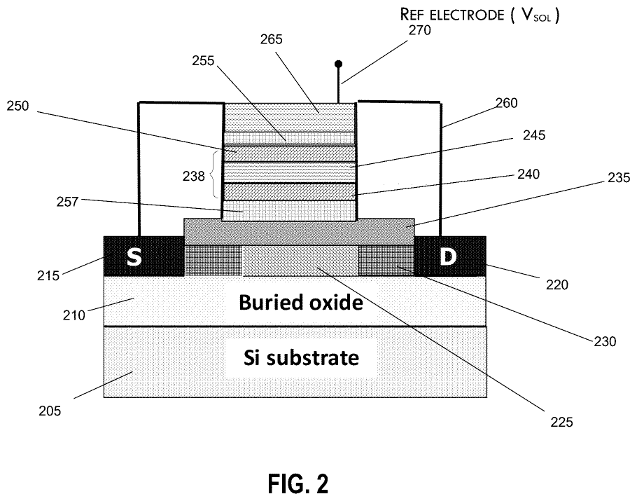

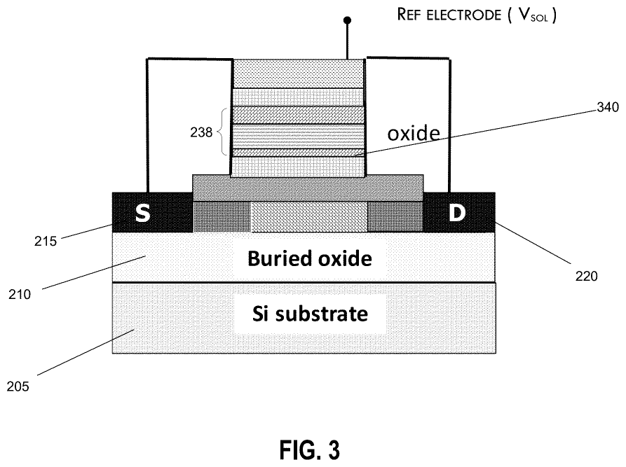

According to illustrative embodiments disclosed herein as shown in FIGS. 2 and 3, the threshold voltage Vₜ of the FET is adjusted during the manufacture of the device according to the thickness of the tri-layer metal electrode material. In addition, a metal oxide layer (e.g., hafnium dioxide (Hf0₂), Silicon dioxide (SiO₂), and/or aluminum oxide (Al₂O₃)) is added on the tri-layer metal electrode material to keep the chemistry of the sensing surface the same as a conventional biosensor. The tri-layer metal electrode controls the threshold voltage Vₜ of the FET via a changing oxygen vacancy concentration in the HfO₂ gate dielectric. Thus, the threshold voltage change is independent of the sensing surface.

### Example Embodiment

FIG. 2 illustrates an FET sensor having a first bottom TiN thickness for a relatively low pH solution, consistent with an illustrative embodiment. There is shown an Si substrate 205, having a buried oxide layer 210 thereon. The buried oxide layer 210 may be constructed of SiO₂. A source 215 and a drain 220 are shown, and there is an Si channel 225 between the source 215 and the drain 220. An SiO₂ layer 235 is arranged on the Si channel 225. A first HfO₂ layer 255 and a second HfO2 layer 257 are shown. A tri-layer metal electrode 238 is shown constructed of a bottom TiN layer 240, an Al alloy layer 245, and a top TiN layer 250, are arranged between the first HfO₂ layer and the second HfO₂ layer. The Al alloy layer 245 may be constructed from an alloy including but not limited to (e.g., TiAl, TiAlC, TaAl, TaAlC, AlC). The bottom TiN layer 240 has a thickness T1, which is similar to a thickness of the top TiN layer 250. The region 230 identifies source and drain regions. The bottom TiN layer 240 is constructed as a stationary knob to control the threshold voltage when a relatively lower pH solution is tested for analytes. An oxide layer 260, such as SiO₂, is arranged along the edges of the tri-layer metal. During operation, a solution 265 has a gate voltage (Vsol) applied by reference electrode 270. The bottom TiN layer thickness T1 is smaller for a higher pH solution (e.g., inversely proportional thickness to pH) or a more negatively charged biolayer.

FIG. 3 illustrates an FET sensor having a second bottom TiN thickness for a relatively high pH solution, consistent with an illustrative embodiment. |Similar to FIG. 2, there is shown an Si substrate 205, having a buried oxide layer 210 thereon. A source 215 and a drain 220 are shown, and there is an Si channel 225 between the source 215 and the drain 220. An SiO₂ layer 235 is arranged on the Si channel. A first HfO₂ layer 255 and a second HfO2 layer 257 are shown. A tri-layer metal electrode 238 is shown constructed of a bottom TiN layer 240, an Al alloy layer 245, and a top TiN layer 250, are arranged between the first HfO₂ layer and the second HfO₂ layer. The Al alloy layer 245 may be constructed from an alloy including but not limited to (e.g., TiAl, TiAlC, TaAl, TaAlC, AlC). The bottom TiN layer 340 has a thickness T2, which is smaller than a thickness of Tin Layer 240 shown in FIG. 2. The bottom TiN layer 340 is also smaller than the top TiN layer 250. The bottom TiN layer 240 is constructed as a stationary knob to control the threshold voltage when a relatively higher pH solution is tested for analytes. An oxide layer 260 is arranged along the edges of the tri-layer metal. During operation, a solution 265 has a gate voltage (Vsol) applied by reference electrode 270.

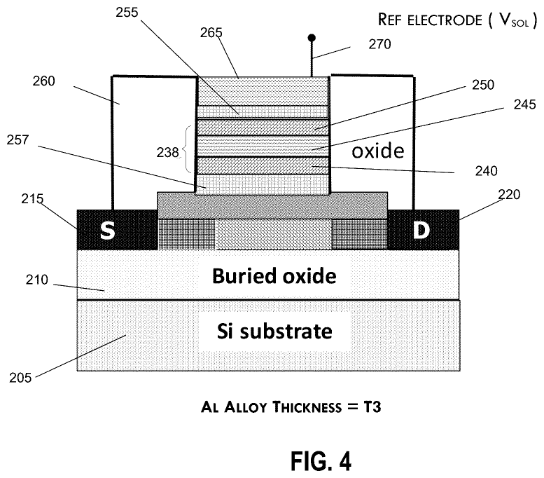

FIG. 4 illustrates an FET sensor with a first Al alloy thickness for a relatively low pH solution, consistent with an illustrative embodiment. There is shown an Si substrate 205, having a buried oxide layer 210 thereon. The buried oxide layer 210 can be made of any suitable dielectric material, such as, for example, silicon oxide. In some embodiments of the present disclosure, the buried oxide layer 210 is formed to a thickness of about 10-200 nm, although other thicknesses are within the contemplated scope of the disclosure. A source 215 and a drain 220 are shown, and there is an Si channel 225 between the source 215 and the drain 220. An SiO₂ layer 235 is arranged on the Si channel. A first HfO₂ layer 255 and a second HfO₂ layer 257 are shown. A tri-layer metal electrode 238 is shown constructed of a bottom TiN layer 240, an Al alloy layer 245, and a top TiN layer 250, are arranged between the first HfO₂ layer and the second HfO₂ layer. The Al alloy layer 245 may be constructed from an alloy including but not limited to (e.g., TiAl, TiAlC, TaAl, TaAlC, AlC). The bottom TiN layer 240 has a thickness which is similar to a thickness of the top TiN layer 250. The Al alloy layer 245 has a thickness T3 and is constructed as a stationary knob to control the threshold voltage when a relatively lower pH solution is tested for analytes. The Al alloy layer 245 thickness T3 is larger for a higher pH solution (e.g., thickness is proportional to pH) or a more negatively charged biolayer.

The oxide layer 260 is arranged along the edges of the tri-layer metal. During operation, a solution 265 has a gate voltage (Vsol) applied by reference electrode 270.

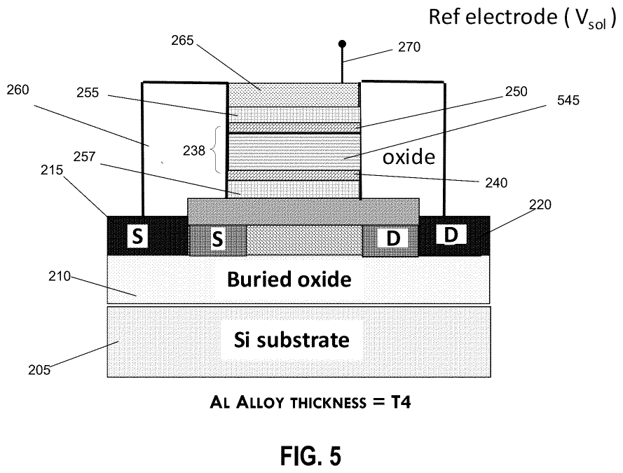

FIG. 5 illustrates an FET sensor with a second Al thickness for a relatively high pH solution, consistent with an illustrative embodiment. Similar to FIG. 4, there is shown a Si substrate 205, having a buried oxide layer 210 thereon. A source 215 and a drain 220 are shown, and there is an Si channel 225 between the source 215 and the drain 220. An SiO₂ layer 235 is arranged on the Si channel. A first HfO₂ layer 255 and a second HfO₂ layer 257 are shown. A tri-layer metal electrode 238 is shown constructed of a bottom TiN layer 240, an Al alloy layer 545, and a top TiN layer 250, are arranged between the first HfO₂ layer and the second HfO₂ layer. The Al alloy layer 245 may be constructed from an alloy including but not limited to (e.g., TiAl, TiAlC, TaAl, TaAlC, AlC). The Al alloy layer 545 has a thickness T4 and is constructed as a stationary knob to control the threshold voltage when a relatively higher pH solution is tested for analytes. The thickness T4 of the Al alloy layer 545 is greater than the thickness of the Al alloy layer 245 shown in FIG. 4. An oxide layer 260 is arranged along the edges of the tri-layer metal electrode. During operation, a solution 265 has a gate voltage (Vsol) applied by reference electrode 270.

### Example Process

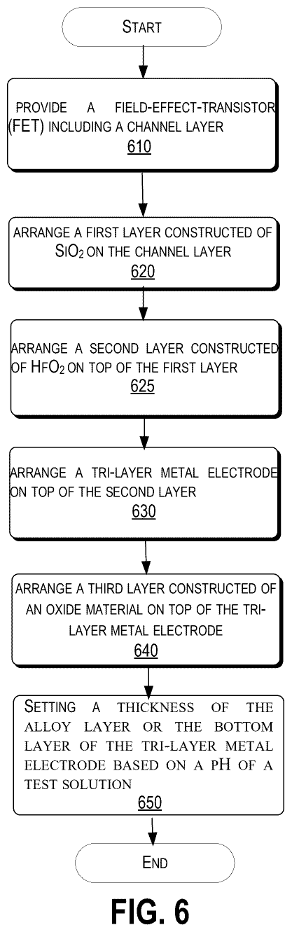

With the foregoing overview of the example architecture, it may be helpful now to consider a high-level discussion of an example process. To that end, FIG. 6 provides a flowchart illustrating the operations to construct an FET sensor consistent with an illustrative embodiment. FIG. 6 may be better understood by viewing FIGS. 2 through 5.

FIG. 6 is shown as a collection of blocks, in a logical order, which represents a sequence of operations that can be implemented in a combination thereof.

A FET transistor including a channel layer is provided such as shown in FIGS. 2 and 4 (operation 610). As shown in FIG. 2, an Si substrate 205 with a buried oxide 210 may be provided. A source 215 and a drain 220 with an Si channel 225 is shown.

A first layer 235 of SiO₂ is constructed on the Si channel 225 (operation 620). Other meal oxides may be used.

A second layer 257 constructed of HfO₂ is arranged on top of the first layer 235.

A tri-layer metal electrode 238 is arranged on top of the second layer (operation 630). The tri-layer metal electrode may include a bottom layer 240 of TiN, an alloy layer 245 on top of the bottom layer, and a top layer 250 of TiN. The tri-layer metal controls the threshold voltage Vₜ of the FET via changing an oxygen vacancy concentration in the HfO₂ dielectric. Thus, the threshold voltage Vₜ is independent of the sensing surface, unlike conventional FET sensors.

A third layer constructed of an oxide material (e.g., HfO₂) that is arranged on top of the tri-layer metal electrode 238 (operation 640). Typically, the oxide material of the bottom layer and the top layer of the tri-layer metal electrode 238 are the same, but the disclosure is not limited to this construction. In addition, the metal oxide used may be HfO₂, SiO₂, or Al₂O₃, just to name a few non-limiting examples of oxide material.

The thickness of the tri-layer metal electrode 238 is set based on the pH of the test solution, and a desired Vₜ (operation 650). For example, a thickness of the alloy layer or the bottom layer of the tri-layer metal electrode 238 can be set for the pH to be used and the Vₜ to be used.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

The flowchart, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A microelectronic structure comprising:
a field-effect-transistor (FET) including a channel layer;
a first layer comprising SiO₂ on the channel layer;
a second layer comprising HfO₂ on top of the first layer;
a tri-layer metal electrode on top of the second layer, the tri-layer metal electrode comprising a bottom layer, an alloy layer on top of the bottom layer of the tri-layer metal electrode, and a top layer; and
a third layer comprising an oxide material on top of the tri-layer metal electrode,
wherein a thickness of the bottom layer of the tri-layer metal electrode is based on a pH of a test solution.

2. The microelectronic structure according to claim 1, wherein a threshold voltage (Vₜ) of the FET is set based on the thickness of the bottom layer of the tri-layer metal electrode.

3. The microelectronic structure according to claim 1, wherein the thickness of the bottom layer is configured to increase based on an increase of the pH of the test solution.

4. The microelectronic structure according to claim 1, wherein the thickness of the bottom layer of the tri-layer metal electrode is between 5 to 100 Angstroms.

5. The microelectronic structure according to claim 1, wherein the alloy layer of the tri-layer metal electrode is an Al alloy selected from the group consisting of TiAl, TiAlC, TaAl, TaAlC, AlC, or Al.

6. The microelectronic structure according to claim 1, wherein:
the bottom layer of the tri-layer metal electrode comprises TiN;
the alloy layer of the tri-layer metal electrode comprises an Al alloy; and
the bottom layer of the tri-layer metal electrode comprises TiN.

7. The microelectronic structure according to claim 1, wherein the oxide material of the third layer is selected from the group consisting of HfO₂, SiO₂, or Al₂O₃.

8. The microelectronic structure according to claim 7, wherein the oxide material of the third layer includes a sensing surface exposed for contact with the test solution.

9. The microelectronic structure according to claim 8, further comprising a reference electrode configured to charge the test solution in contact with the sensing surface of the oxide material of the third layer.

10. A microelectronic structure comprising:
a field-effect-transistor (FET) including a channel layer;
a first layer comprising SiO₂ on the channel layer;
a second layer comprising HfO₂ on top of the first layer;
a tri-layer metal electrode on top of the second layer, the tri-layer metal electrode comprising a bottom layer, an alloy layer on top of the bottom layer, and a top layer; and
a third layer comprising an oxide material on top of the tri-layer metal electrode,
wherein a thickness of the alloy layer of the tri-layer metal electrode is based on a pH of a test solution.

11. The microelectronic structure according to claim 10, wherein a threshold voltage (Vₜ) of the FET is set based on the thickness of the alloy layer of the tri-layer metal electrode.

12. The microelectronic structure according to claim 10, wherein the thickness of the alloy layer is configured to decrease based on an increase of the pH of the test solution.

13. The microelectronic structure according to claim 10, wherein the thickness of the alloy layer of the tri-layer metal electrode is between 5 to 100 Angstroms.

14. The microelectronic structure according to claim 10, wherein the alloy layer of the tri-layer metal electrode is an Al alloy selected from the group consisting of TiAl, TiAlC, TaAl, TaAlc, AiC, or Al.

15. The microelectronic structure according to claim 10, wherein:
the bottom layer of the tri-layer metal electrode comprises TiN;
the alloy layer of the tri-layer metal electrode comprises an Al alloy; and
the bottom layer of the tri-layer metal electrode comprises TiN.

16. The microelectronic structure according to claim 10, wherein the oxide material of the third layer is selected from the group consisting of HfO₂, SiO₂, or Al₂O₃.

17. The microelectronic structure according to claim 16, wherein the oxide material of the third layer includes a sensing surface exposed for contact with the test solution.

18. The microelectronic structure according to claim 17, further comprising a reference electrode arranged to charge the test solution in contact with the sensing surface of the oxide material of the third layer.

19. A method of manufacturing a microelectronic structure for bio-sensing, the method comprising:
providing a field-effect-transistor (FET) including a channel layer;
arranging a first layer constructed of SiO₂ on the channel layer;
arranging a second layer constructed of HfO₂ on top of the first layer;
arranging a tri-layer metal electrode on top of the second layer, the tri-layer metal electrode includes a bottom layer, an alloy layer on top of the bottom layer, and a top layer; and
arranging a third layer comprising an oxide material on top of the tri-layer metal electrode;
wherein a thickness of the alloy layer or the bottom layer of the tri-layer metal electrode is based on a pH of a test solution.

20. The method according to claim 19, further comprising setting a threshold voltage (Vₜ) of the FET based on the thickness of the bottom layer or the alloy layer of the tri-layer metal electrode.
